(19) United States
(12) Patent Application Publication
(10) Pub. No.: US 2025/0118695 A1
(43) Pub. Date: Apr. 10, 2025

(54) PACKAGE COMPONENT AND FORMING METHOD THEREOF

(71) Applicant: TAIWAN SEMICONDUCTOR MANUFACTURING COMPANY LTD., HSINCHU (TW)

(72) Inventors: MING-WEI PENG, TAOYUAN CITY (TW); HUNG EN HSU, TAIPEI CITY (TW); KUO-CHING HSU, NEW TAIPEI CITY (TW)

(21) Appl. No.: 18/484,403

(22) Filed: Oct. 10, 2023

(51) Int. Cl. H01L 23/00; H01L 21/56; H01L 23/31

(52) U.S. Cl. CPC H01L 24/20; H01L 21/56; H01L 23/3121; H01L 24/19; H01L 2224/19; H01L 2224/214; H01L 2224/215; H01L 2924/01013; H01L 2924/01022; H01L 2924/01029; H01L 2924/01074

(57) ABSTRACT

A package component includes an insulating substrate, a semiconductor structure, a first conductive line and a conductive pad. The semiconductor structure is disposed in the insulating substrate and separated from the insulating substrate. The first conductive line is disposed on a first side of the insulating substrate. The conductive pad is disposed on a first side of the semiconductor structure. The first conductive line and the conductive pad include a same material. A surface roughness of the conductive pad is greater than a surface roughness of the first conductive line.

### BACKGROUND

The semiconductor industry has experienced rapid growth due to ongoing improvements in the integration density of a variety of electronic components (e.g., transistors, diodes, resistors, capacitors, etc.). Such improvements in integration density have resulted from iterative reduction of minimum feature size, which allows more components to be integrated into a given area. As demand for smaller electronic devices has grown, a need for smaller and more creative packaging techniques of semiconductor dies has emerged. A printed circuit board (PCB) serves to electrically connect electronic components thereto and mechanically fix them in place.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIGS. 1 to 11 are cross-sectional views illustrating a package component at different fabrication stages constructed according to aspects of one or more embodiments of the present disclosure.

FIG. 12 is a flowchart representing a method for forming a package component according to aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A package component such as a printed circuit board (PCB) serves to electrically connect electronic components to the PCB and mechanically fix the electronic components on the PCB. The PCB includes insulators and conductive lines adhered to the insulators. In some embodiments, the insulators and the conductive lines form complete layers of materials on a substrate. The substrate may include active and passive devices (not shown), or may be free of either active devices, passive device, or both. A wide variety of devices such as transistors, capacitors, resistors, combinations of these, and the like may be formed using any suitable method. For example, the substrate may include at least a capacitor embedded therein and coupled to the conductive lines through conductive pads. In some comparative approaches, metal diffusion and coefficient of thermal expansion (CTE) mismatch may occur after thermal stress, thereby forming a path between two adjacent conductive pads. An approach to mitigate such issue is therefore needed.

Some embodiments of the present disclosure provide a package component and a forming method thereof that provide one or more improvements over existing approaches. The present disclosure relates to a package component that includes conductive pads having different morphologies for an embedded capacitor. In some embodiments, a surface roughness of the conductive pads for the embedded capacitor is increased such that at an interface of the conductive pads and insulating layers overlying the conductive pads is increased. Accordingly, negative effects caused by CTE mismatch are mitigated and metal diffusion may be blocked by the insulating layers, and thus reliability of the package component is improved.

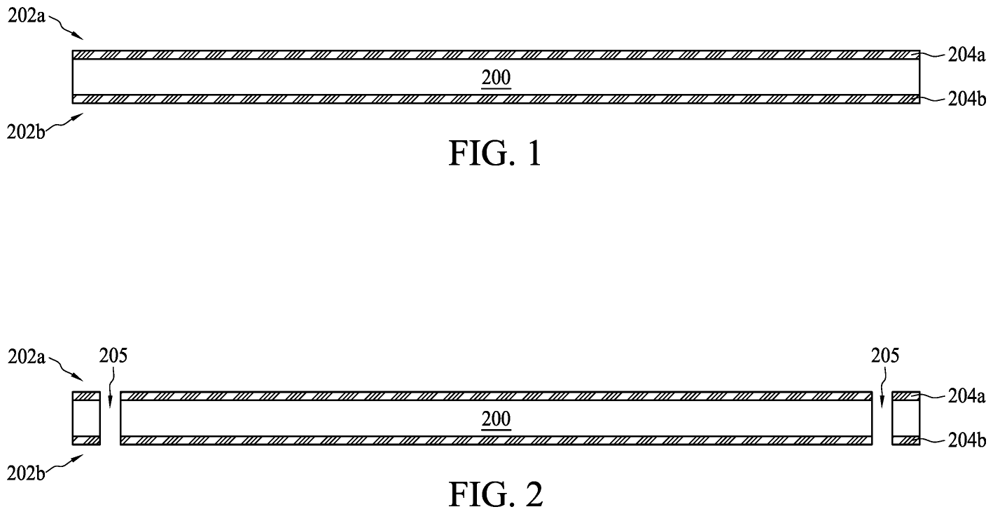

FIGS. 1 to 11 are cross-sectional views illustrating a package component 120 at different fabrication stages constructed according to aspects of one or more embodiments of the present disclosure.

Referring to FIG. 1, an insulating substrate 200 (which is sometimes referred to as a substrate core) is provided or received. The insulating substrate 200 may be an insulating core and may include one or more layers of insulating materials. In some embodiments, the insulating substrate 200 may include a material such as printed circuit board (PCB) material, fiberglass-reinforced resin material, build-up film such as Ajinomoto build-up film (ABF), pre-impregnated composite fiber (pre-preg) material, epoxy, molding compound, epoxy molding compound, polymer material such as polytetrafluoroethylene (PTFE) or polyimide, paper, silica filler, glass fiber, non-woven glass fabric, glass, ceramic, other laminates, the like, or combinations thereof. In some embodiments, the insulating substrate 200 may be formed from materials that help achieve a CTE match with silicon, but the disclosure is not limited thereto.

The insulating substrate 200 has a first side 202a and a second side 202b opposite to the first side 202a. In some embodiments, seed layers 204a and 204b may be formed on the insulating substrate 200 on the first side 202a and/or the second side 202b. The seed layers 204a and 204b may be one or more layers of copper, titanium, nickel, aluminum, compositions thereof, or the like, and are deposited or laminated onto the first and second sides 202a and 202b of the insulating substrate 200. In some embodiments, the insulating substrate 200 and the seed layers 204a and 204b are copper-clad epoxy-impregnated glass-cloth laminate, a copper-clad polyimide-impregnated glass-cloth laminate, or the like. In some embodiments, the insulating substrate 200 and the seed layers 204a and 204b may be a double-sided copper-clad laminate (CCL), as shown in FIG. 1. In some alternative embodiments, the insulating substrate 200 and the seed layer 204a or 204b are a single-sided copper-clad laminate.

Referring to FIG. 2, in some embodiments, openings 205 are formed in the insulating substrate 200 and the seed layers 204a and 204b. In some embodiments, the openings 205 are formed by laser drilling. In other embodiments, mechanical drilling with a drill bit may be used to form the openings 205. The openings 205 may have any top-view shape, such as a polygon, a circle, or the like. In some embodiments, a cleaning operation may be performed to clean areas near the openings 205 that may have been smeared with removed materials of the insulating substrate 200 and the seed layers 204a and 204b. In some embodiments, the cleaning operation may be a desmearing operation. The desmearing may be accomplished mechanically (e.g. a blasting with a fine abrasive in a wet slurry), chemically (e.g., rinsing with combination of organic solvents, permanganate, or the like), or by a combination of the mechanical and chemical operations.

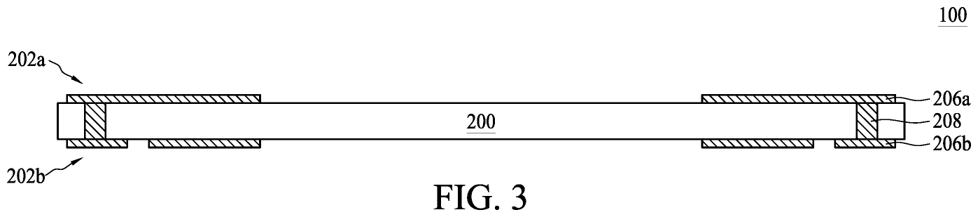

Referring to FIG. 3, in some embodiments, conductive lines 206a and 206b are formed over the insulating substrate 200 on the first side 202a and the second side 202b. Further, conductive vias 208 are formed to fill the openings 205. The conductive lines 206a and 206b and the conductive vias 208 may include copper, titanium, tungsten, aluminum, or the like. In some embodiments, the conductive lines 206a and 206b and the conductive vias 208 may be formed from a same material or different materials. In some embodiments, the conductive lines 206a and 206b and the conductive vias 208 may be formed by a same operation or different operations. In some embodiments, the conductive vias 208 may be formed prior to the forming of the conductive lines 206a and 206b. In such embodiments, a first plating operation, such as an electroless plating, may be used to fill the openings 205 with a conductive material, thereby forming the conductive vias 208. Additionally, in such embodiments, seed layers may be formed in the openings 205 prior to the electroless plating, though not shown. Another plating operation, may be performed to form the conductive lines 206a and 206b. In such embodiments, a patterned photoresist (not shown) may be formed over the seed layers 204a and 204b. The patterned photoresist may have openings exposing the seed layers 204a and 204b. A conductive material is then formed in the openings of the patterned photoresist and on the exposed seed layers 204a and 204b by using an electroplating, an electroless plating, or the like. In such embodiments, the patterned photoresist and portions of the seed layers 204a and 204b that are free of the conductive material are then removed. As shown in FIG. 3, remaining portions of the seed layers 204a and 204b and the conductive material form the conductive lines 206a and 206b.

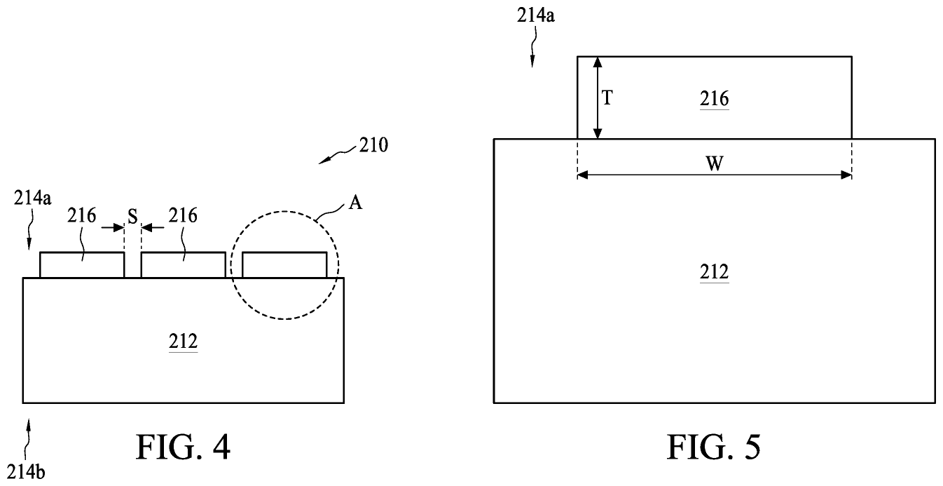

Referring to FIGS. 4 and 5, wherein FIG. 5 is a partially enlarged view of circle A of FIG. 4, in some embodiments, a semiconductor structure 210 is provided or received. The semiconductor structure 210 may include a semiconductor substrate 212. The semiconductor substrate 212 has a first side 214a and a second side 214b opposite to the first side 214a. In some embodiments, devices may be formed in the semiconductor substrate 212. For example, at least a capacitor is formed in the semiconductor substrate 212. Additionally, the capacitor is formed on the first side 214a of the semiconductor substrate 212. A plurality of conductive pads 216 may be formed over the semiconductor substrate 212 on the first side 214a. Further, the conductive pads 216 are electrically connected to the device (i.e., the capacitor) formed in the semiconductor substrate 212. The conductive pads 216 provide electrical connection between the device formed in the semiconductor substrate 212 and external elements. In some embodiments, the conductive pads 216 may include copper, titanium, tungsten, aluminum, or the like. Further, the conductive pads 216 may include materials same as those of the conductive lines 206a and 206b, and the conductive vias 208.

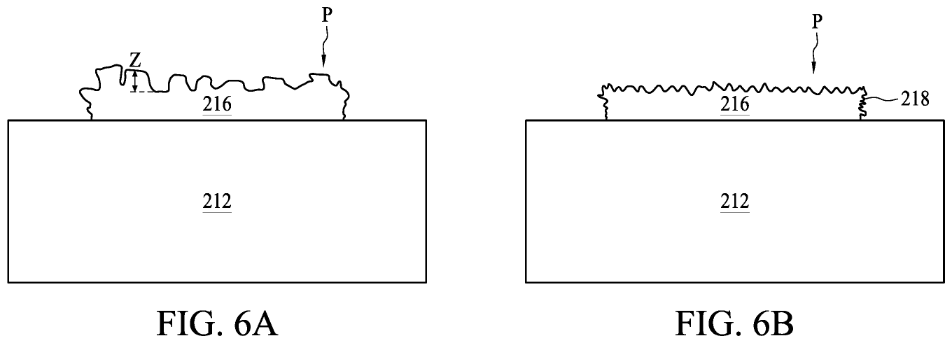

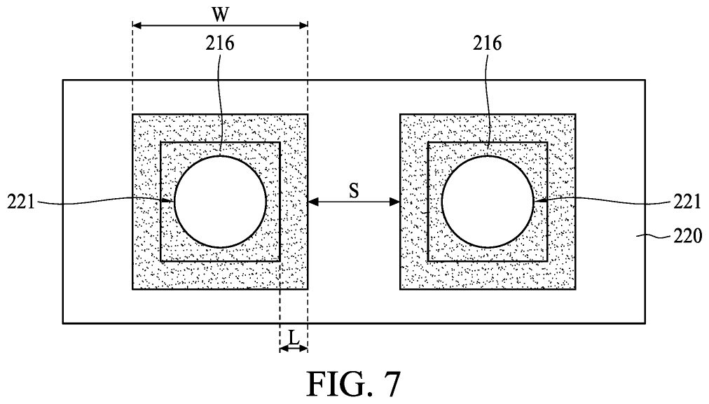

Referring to FIG. 6A, a top surface and side surfaces of the conductive pads 216 are exposed. In some embodiments, both the top surface and the side surfaces of the conductive pads 216 are entirely exposed. In other embodiments, the conductive pads 216 may be partially embedded in the semiconductor substrate 212; therefore, the top surface of the conductive pad 216 is entirely exposed while the side surfaces of the conductive pad 216 are partially exposed. In some embodiments, a width W of the conductive pad 216 may be between approximately 100 micrometers and approximately 250 micrometers, but the disclosure is not limited thereto. In some embodiments, a thickness T, also referred to as a length of an exposed portion of the side surface, of the conductive pad 216 may be between approximately 7 micrometers and approximately 12 micrometers, but the disclosure is not limited thereto. In some embodiments, a spacing distance S (shown in FIG. 7) between two adjacent conductive pads 216 may be between approximately 12 micrometers and approximately 30 micrometers, but the disclosure is not limited thereto.

Referring to FIG. 6A, the exposed top surface and side surfaces of the conductive pad 216 are treated. In some embodiments, the treatment of the surfaces of the conductive pad 216 includes an etching. In some embodiments, the etching includes a wet etching, but the disclosure is not limited thereto. In such embodiments, the exposed top surfaces and side surfaces of the conductive pads 216 are treated to increase a surface roughness. For example, an arithmetic average roughness (Ra) of the conductive pad 216 is between approximately 0.3 micrometer and approximately 0.8 micrometer after the surface treatment. In some embodiments, a plurality of teeth or peaks P are obtained by the surface treatment. A quantity of the peaks P in 1*1 mm² of the conductive pad 216 may be between approximately 300 and approximately 1000. In some embodiments, a height Z measured from a top of the peak P to a bottom of a valley between peaks P may be between approximately 0.3 micrometer and approximately 1 micrometer. In embodiments where the surface treatment includes etching, the thickness T of the conductive pad 216 may be than 7 micrometers, which may reduce a structural strength of the conductive pad 216 and increase a capacitance of the conductive pad 216.

Referring to FIG. 6B, in some embodiments, the treatment of the surface of the conductive pad 216 further includes forming a bond film 218 over the surfaces of the conductive pad 216. In such embodiments, the bond film 218 may include copper oxide formed by surface treatment. In some embodiments, the forming of the bond film 218 is optional.

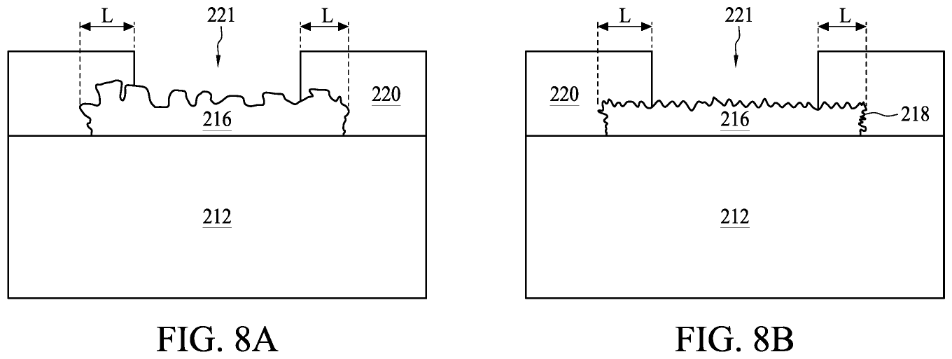

Please refer to FIGS. 7, 8A and 8B, wherein FIG. 7 is a top view of FIGS. 8A and 8B. After the treatment of the surfaces of the conductive pads 216, an insulating layer 220 is formed over the semiconductor substrate 212 on the first side 214a. In some embodiments, the insulating layer 220 may include polyimide (PI), but the disclosure is not limited thereto. A thickness of the insulating layer 220 may be between approximately 3 micrometers and approximately 11 micrometers. In some embodiments, the insulating layer 220 includes a plurality of openings 221 exposing a portion of each conductive pad 216. In other words, the insulating layer 220 covers another portion of each conductive pad 216, as shown in FIGS. 8A and 8B. A length L of the portion of the conductive pad 216 covered by the insulating layer 220 may be between approximately 2.5 micrometers and approximately 10 micrometers. In some comparative approaches, when the length L is less than 2.5 micrometers, peeling of the insulating layer 220 may occur and thus an undesired connection between two adjacent conductive pads 216 may occur. In other comparative approaches, when the length L is greater than 10 micrometers, the opening 221 of the insulating layer 220 is not big enough to provide connection or may require further effort during forming of an electrical connection to the conductive pad 216.

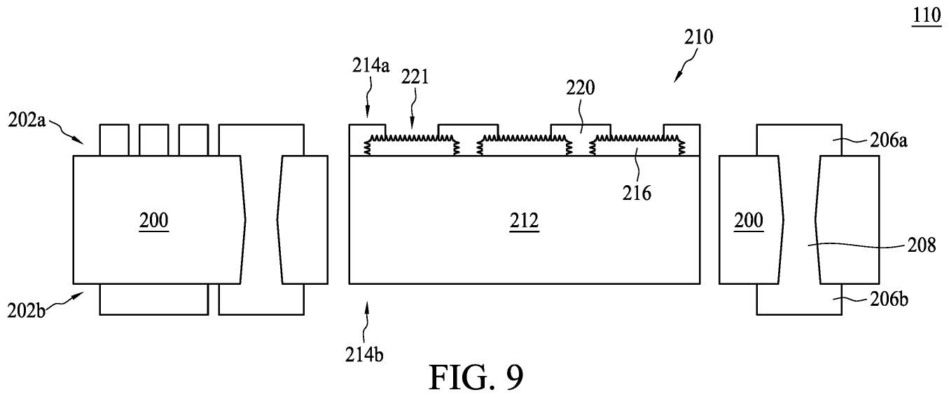

Referring to FIG. 9, in some embodiments, the semiconductor structure 210 is disposed in the insulating substrate 200. In such embodiments, a carrier wafer (not shown) may be provided to support the insulating substrate 200. A portion of the insulating substrate 200 is removed. In some embodiments, a recess may be formed in the insulating substrate 200. In other embodiments, a hollow portion may be formed in the insulating substrate 200. Subsequently, the semiconductor structure 210 is disposed in the recess or the hollow portion of the insulating substrate 200. As shown in FIG. 9, the first side 214a of the semiconductor structure 210 and the first side 202a of the substrate 200 face a same direction, while the second side 214b of the semiconductor structure 210 and the second side 202b of the substrate 200 face a same direction. Accordingly, the conductive pads 216 and the conductive lines 206a are disposed over a same side. In some embodiments, the semiconductor structure 210 is separated from the substrate 200. In addition, the insulating layer 220 and the conductive pads 216 are separated from the substrate 200 and the conductive lines 206a and 206b.

Additionally, in some embodiments, the insulating substrate 200 (and the conductive lines 206a and 206b and the conductive vias 208) and the semiconductor structure 210 may be formed or prepared from different operations; therefore, a thickness of the semiconductor substrate 212 may be different from a thickness of the insulating substrate 200. Additionally, the thickness T of the conductive pads 216 and a thickness of the insulating layer 220 may be different from a thickness of the conductive lines 206a.

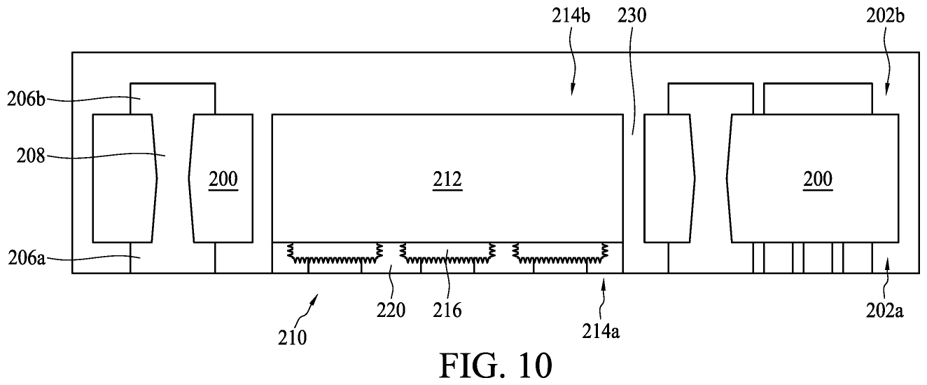

Referring to FIG. 10, in some embodiments, an insulating material is formed to fill space between the semiconductor structure 210 and the insulating substrate 200, thereby securing and embedding the semiconductor structure 210 in the insulating substrate 200. In some embodiments, the insulating material serves as an insulating wall 230, which not only secures the semiconductor structure 210 in the insulating substrate 200, but also separates the semiconductor structure 210 from the insulating substrate 200.

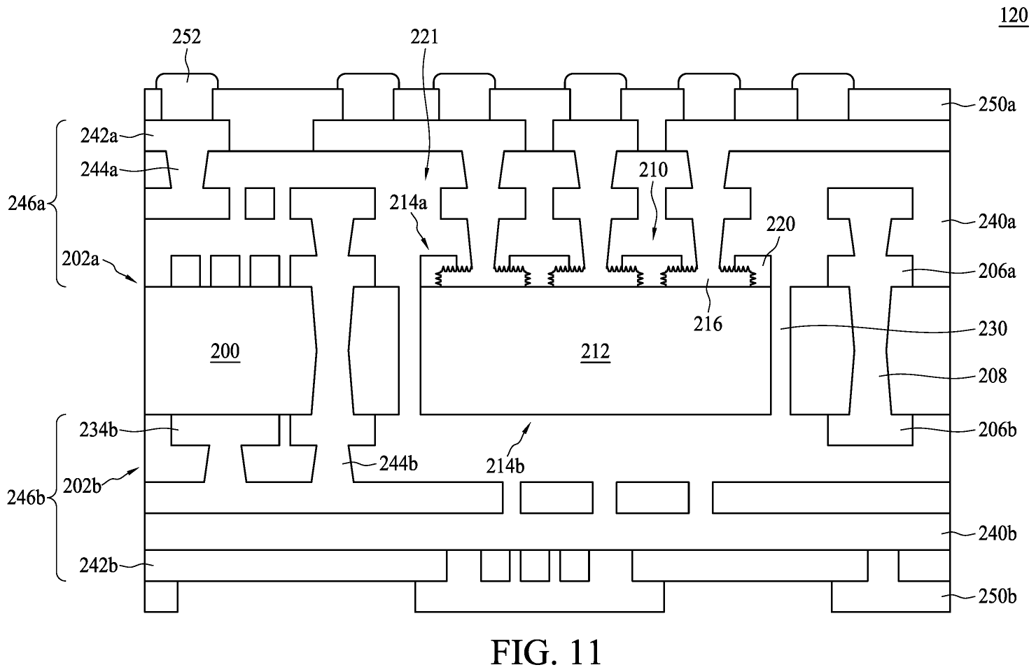

Referring to FIG. 11, insulating layers 240a, conductive lines 242a, and conductive vias 244a are formed over the first side 202a of the insulating substrate 200. Insulating layers 240b, conductive lines 242b, and conductive vias 244b are formed over the second side 202b of the insulating substrate 200. In some embodiments, the insulating layers 240a and 240b can be formed of an ABF, pre-preg, molding film, or the like. In some embodiments, the insulating layers 240a and 240b can be formed of a polymer, such as polybenzoxazole (PBO), polyimide, benzocyclobutene (BCB), or the like. In other embodiments, the insulating layers 240a and 240b can be formed of a nitride such as silicon nitride; an oxide such as silicon oxide, phosphosilicate glass (PSG), borosilicate glass (BSG), boron-doped phosphosilicate glass (BPSG), or the like; or other suitable materials. The insulating layers 240a and 240b may be formed by any acceptable deposition process, such as spin coating, chemical vapor deposition (CVD), laminating, the like, or a combination thereof.

In some embodiments, the conductive lines 242a and 242b and the conductive vias 244a and 244b include material same as those of the conductive lines 206a and 206b and the conductive pads 216, such as copper, titanium, tungsten, aluminum, alloys thereof, combinations thereof, or the like. The conductive lines 242a and 242b and the conductive vias 244a and 244b may be formed by plating (e.g., electroplating or electroless plating, or the like). As an example, to form the conductive lines 242a and 242b and the conductive vias 244a and 244b, a seed layer (not shown) is formed. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is then formed and patterned on the seed layer. The photo resist may be formed by spin coating or the like and may be exposed to light for patterning. The patterning forms openings through the photo resist to expose the seed layer. A conductive material is formed in the openings of the photo resist and on exposed portions of the seed layer. The conductive material may be formed by plating, such as electroplating or electroless plating, or the like. The conductive material may comprise a metal, like copper, titanium, tungsten, aluminum, or the like. Next, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as wet or dry etching. Remaining portions of the seed layer and conductive material form the conductive lines 242a and 242b and the conductive vias 244a and 244b.

In some embodiments, the insulating layers 240a, the conductive lines 242a and the conductive vias 244a are referred to as a redistribution layer (RDL) 246a over the first side 202a, while the insulating layers 240b, the conductive lines 242b and the conductive vias 244b are referred to as another RDL 246b over the second side 202b. Any number of insulating layers 240a and 240b, conductive lines 242a and 242b, and conductive vias 244a and 244b may be formed in the RDLs 246a and 246b on either or both sides 202a and 202b; the numbers of such elements shown in FIG. 11 is for illustration only and is not intended to be limiting. Further, the RDL 246a and the RDL 246b are electrically connected by the conducive vias 208 in the insulating substrate 200.

In some embodiments, a solder resist 250a may be formed over topmost conductive lines 242a on the first side 202a of the insulating substrate 200. A plurality of conductive connectors 252 are formed over the RDL 246a and coupled to the insulating substrate 200 through the RDL 246a. In some embodiments, under bump metallizations (UBM) may be formed prior to the forming of the conductive connectors 252. The conductive connectors 252 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 252 may include a conductive material such as solder, copper, aluminum, gold, nickel, silver, palladium, tin, the like, or a combination thereof. In some embodiments, the conductive connectors 252 are formed by initially forming a layer of solder through evaporation, electroplating, printing, solder transfer, ball placement, or the like. After the layer of solder has been formed on the structure, a reflow may be performed in order to shape the conductive material into desired bump shapes. In another embodiment, the conductive connectors 252 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on top of the metal pillars. The metal cap layer may include nickel, tin, tin-lead, gold, silver, palladium, indium, nickel-palladium-gold, nickel-gold, the like, or a combination thereof, and may be formed by a plating process.

In some embodiments, a solder resist 250b may be formed over the RDL 246b on the second side 202b of the insulating substrate 200. In some embodiments, conductive connectors may be formed over the RDL 246b and coupled to the insulating substrate 200, though not shown.

In some embodiments, two or more core substrates are attached, via solder joints or the like, to the RDLs 246a and 246b.

Accordingly, a package component 120 is provided. The package component 120 includes an insulating substrate 200, and the insulating substrate 200 has a first side 202a and a second side 202b opposite to the first side 202a. The insulating substrate 200 further includes a plurality of conductive vias 208 disposed and embedded therein. The package component 120 includes a RDL 246a disposed over the first side 202a, and an RDL 246b disposed over the second side 202b.

As shown in FIG. 11, the RDL 246a may include a plurality of conductive lines 206a and 242a disposed in insulating layers 240a and connected by conductive vias 244a. In some embodiments, the conductive lines 206a are referred to as bottommost layers of the RDL 246a and are coupled to the conductive vias 208. The RDL 246b may include a plurality of conductive lines 206b and 242b disposed in insulating layers 240b and connected by conductive vias 244b. The conductive lines 206b are referred to as bottommost layers of the RDL 246b and are coupled to the conductive vias 208. Further, the RDL 246a and the RDL 246b are electrically connected by the conductive vias 208.

The package component 120 further includes a semiconductor structure 210. The semiconductor structure 210 includes a semiconductor substrate 212 having devices, such as capacitors, formed therein. As shown in FIG. 11, the semiconductor structure 210, although disposed within the insulating substrate 200, is separated from the insulating substrate 200. In some embodiments, the semiconductor structure 210 is separated from the insulating substrate 200 by an insulating wall 230. In some embodiments, the package component 120 can be described as including a core substrate, and the core substrate includes an insulating portion 200 and a semiconductor portion 212.

The semiconductor structure 210 has a first side 214a and a second side 214b. The semiconductor structure 210 may be a die that including passive device(s), for example but not limited thereto, a capacitor. In some embodiments, the semiconductor structure 210 is disposed in the insulating substrate 200 with the first side 214a facing a same direction or a same side as the first side 202a of the insulating substrate 200. A plurality of conductive pads 216 are disposed on the first side 214a of the semiconductor structure 210. An insulating layer 220 is disposed over the conductive pads 216 on the first side 214a. Further, the insulating layer 220 covers a first portion of each conductive pad 216, and exposes another portion of each conductive pad 216. The insulating layer 240a covers and is in contact with a second portion of each conductive pad 216 and exposes another portion of each conductive pad 216. In some embodiments, the insulating layer 240a covers a portion of the conductive lines 206a. A portion of the pad 216 that is exposed through both the insulating layer 220 and the insulating layer 240a is coupled and electrically connected to the RDL 246a, while a portion of the conductive line 206a that is exposed through the insulating layer 240a is coupled and electrically connected to the RDL 246a, as shown in FIG. 11.

Additionally, a surface of the semiconductor substrate 212 on the second side 214b may be entirely in contact with the insulating layer 240b, but the disclosure is not limited thereto.

In some embodiments, the conductive pads 216 and the conductive lines 206a may include a same conductive material. However, a thickness of the conductive pad 216 and a thickness of the conductive line 206a may be different. Moreover, a surface roughness of the conductive pad 216 is greater than a surface roughness of the conductive line 206a. In some embodiments, an arithmetic average roughness (Ra) of the conductive pad 216 is between approximately 0.3 micrometer and approximately 0.8 micrometer.

It should be noted that the conductive pads 216 are in contact with the semiconductor substrate 212, the insulating layer 220 and the insulating layer 240a. Therefore, four different materials, such as a conductive material of the conductive pads, a semiconductor material of the semiconductor substrate 212, an insulating material of the insulating layer 220 and another insulating material of the insulating layer 240a, with four different CTEs, impose complicated thermal stresses on the conductive pads 216. In some embodiments, the rough surfaces of the conductive pads 216 provide adhesion between the conductive pads 216 and the insulating layer 220. Accordingly, the insulating layer 220 that provides electrical isolation between the conductive pads 216 is adhered and secured to the conductive pads 216 even under such thermal stresses.

In addition, metal diffusion may occur between two adjacent conductive pads 216 during operation. However, the insulating layer 220 that is adhered and secured to the conductive pads 216 due to the rough surface of the conductive pads 216 provides sufficient isolation and thus the metal diffusion may be blocked. As a result, reliability of the insulating layer 220 and reliability of package component 120 are improved.

In some embodiments, the package component 120 can be used in various packages. For example, an integrated circuit package can include a plurality of integrated circuit dies, such as a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), an input/output (I/O) die, the like, or combinations thereof. The integrated circuit dies may be formed in one or more wafers, which may include different device regions that are singulated in subsequent steps. The integrated circuit dies may be packaged with other similar or different integrated circuit dies using manufacturing techniques. Such integrated circuit package may include the package component 120 providing electrical path and connection between, for example, the logic die and the I/O dies, as well as connection from the integrated circuit package to other elements.

The structures of the present disclosure are not limited to the above-mentioned embodiments and may have other different embodiments. To simplify the description and for convenience of comparison between each of the embodiments of the present disclosure, identical (or like) components in each of the following embodiments are marked with identical (or like) numerals. For making it easier to compare differences between the embodiments, the following description will detail dissimilarities among different embodiments, while identical features, values and definitions will not be repeated.

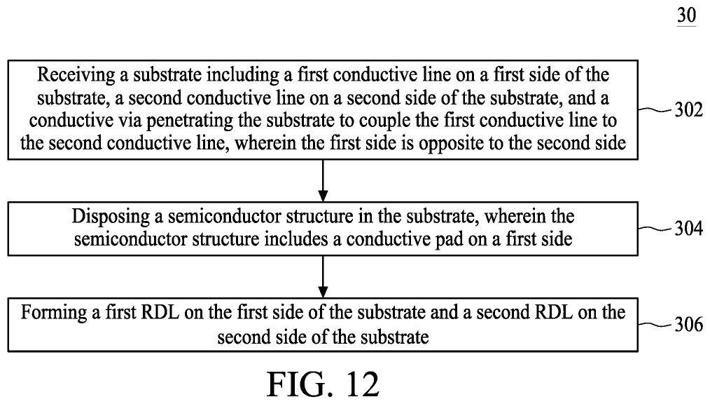

FIG. 12 is a flowchart representing a method 30 for forming a package component according to aspects of one or more embodiments of the present disclosure. While the disclosed method 30 is illustrated and described herein as a series of acts or operations, it will be appreciated that an order of the illustrated acts or operations is not to be interpreted in a limiting sense. For example, some operations may be performed in a different order and/or concurrently with other acts or operations apart from those illustrated and/or described herein. In addition, not all illustrated operations may be required to implement one or more aspects or embodiments of the invention described herein. Further, one or more of the operations described herein may be carried out in one or more separate operations and/or phases.

In operation 302, an insulating substrate 200 is received. FIGS. 1 to 3 illustrate cross-sectional views of an intermediate package component 100 according to some embodiments corresponding to operation 302. In some embodiments, the operation 302 may include further steps or processes as described above and depicted in FIGS. 1 to 3; therefore, those repeated descriptions are omitted for brevity.

In operation 304, a semiconductor structure 210 is disposed in the substrate. FIGS. 4 to 9 illustrate cross-sectional views of an intermediate package component 110 according to some embodiments corresponding to operation 304.

In operation 306, an RDL 246a is formed on a first side 202a of the insulating substrate 200, and an RDL 246b is formed on a second side 202b of the insulating substrate 200. FIGS. 10 and 11 illustrate cross-sectional views of an intermediate package component 120 according to some embodiments corresponding to operation 306.

The method 30 is described for a purpose of illustrating concepts of the present disclosure and the description is not intended to limit the present disclosure beyond what is explicitly recited in the claims. Additional operations can be provided before, during, and after the method described above and illustrated in FIG. 12, and some operations described can be replaced, eliminated, or moved around for additional embodiments of the method.

According to some embodiments of the present disclosure, a package component and a forming method thereof are provided to improve upon existing approaches. The present disclosure relates to a package component that includes conductive pads having different morphology for the embedded capacitor. In some embodiments, a surface roughness of the conductive pads for the embedded capacitor is increased such that adhesion between the conductive pads and insulating layers overlying the conductive pads is increased. Accordingly, negative effects of CTE mismatch are mitigated and metal diffusion may be blocked by the insulating layers, and thus reliability of the package component is improved.

In accordance with some embodiments of the present disclosure, a package component is provided. The package component includes an insulating substrate, a semiconductor structure, a first conductive line and a conductive pad. The semiconductor structure is disposed in the insulating substrate and separated from the insulating substrate. The first conductive line is disposed on a first side of the insulating substrate. The conductive pad is disposed on a first side of the semiconductor structure. The first conductive line and the conductive pad include a same material. A surface roughness of the conductive pad is greater than a surface roughness of the first conductive line.

In accordance with some embodiments of the present disclosure, a package component is provided. The package component includes a substrate, a first conductive line, a second conductive line, a conductive pad, a conductive via, and an insulating wall. The substrate includes an insulating portion and a semiconductor portion. The first conductive line is disposed over the insulating portion on a first side of the substrate. The second conductive line is disposed over the insulating portion on a second side of the substrate. The conductive pad is disposed over the semiconductor portion on the first side of the substrate. The conductive via is disposed in the insulating portion of the substrate, and electrically connects the first conductive line to the second conductive line. The insulating wall is disposed between the insulating portion and the semiconductor portion. A surface roughness of the conductive pad is greater than a surface roughness of the first conductive line and the second conductive line.

In accordance with some embodiments of the present disclosure, a method of forming a package component is provided. The method includes following operations. A substrate is provided or received. The substrate includes a first conductive line on a first side of the substrate, a second conductive line on a second side of the substrate, and a conductive via penetrating the substrate to couple the first conductive line to the second conductive line. The first side of the substrate is opposite to the second side of the substrate. A semiconductor structure is disposed in the substrate. The semiconductor structure includes a conductive pad on a first side of the semiconductor structure. A first RDL is formed on the first side of the substrate, and a second RDL is formed on the second side of the substrate. A surface roughness of the conductive pad is different from a surface roughness of the first conductive line and the second conductive line.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package component, comprising:
an insulating substrate;
a semiconductor structure disposed in the insulating substrate and separated from the insulating substrate;
a first conductive line disposed on a first side of the insulating substrate; and
a conductive pad disposed on a first side of the semiconductor structure,
wherein the first conductive line and the conductive pad comprise a same material, and a surface roughness of the conductive pad is greater than a surface roughness of the first conductive line.

2. The package component of claim 1, wherein an arithmetic average roughness (Ra) of the conductive pad is between approximately 0.3 micrometer and approximately 0.8 micrometer.

3. The package component of claim 1, further comprising:
a first insulating layer covering a first portion of the conductive pad; and
a second insulating layer covering a second portion of the conductive pad, the first insulating layer and a portion of the first conductive line.

4. The package component of claim 1, further comprising a second conductive line disposed on a second side of the insulating substrate, wherein the second side of the insulating substrate is opposite to the first side of the insulating substrate.

5. The package component of claim 4, further comprising a conductive via penetrating the insulating substrate, wherein the conductive via electrically connects the first conductive line and the second conductive line.

6. The package component of claim 4, further comprising:
at least a third conductive line on the first side of the insulating substrate and electrically connected to the conductive pad and the first conductive line; and
at least a fourth conductive line on the second side of the insulating substrate and electrically connected to the second conductive line.

7. The package component of claim 1, wherein the semiconductor structure is separated from the insulating substrate by an insulating wall.

8. A package component, comprising:
a substrate comprising an insulating portion and a semiconductor portion;
a first conductive line disposed over the insulating portion on a first side of the substrate;
a second conductive line disposed over the insulating portion on a second side of the substrate, wherein the second side is opposite to the first side;
a conductive pad disposed over the semiconductor portion on the first side of the substrate;
a conductive via disposed in the insulating portion of the substrate, wherein the conductive via electrically connects the first conductive line to the second conductive line; and
an insulating wall disposed between the insulating portion and the semiconductor portion,
wherein a surface roughness of the conductive pad is greater than a surface roughness of the first conductive line and the second conductive line.

9. The package component of claim 8, wherein an arithmetic average roughness (Ra) of the conductive pad is between approximately 0.3 micrometer and approximately 0.8 micrometer.

10. The package component of claim 8, wherein the first conductive line, the second conductive line and the conductive pad comprise a same material.

11. The package component of claim 8, wherein a thickness of the conductive pad is different from a thickness of the first conductive line.

12. The package component of claim 8, further comprising:
a first insulating layer covering a first portion of the conductive pad; and
a second insulating layer covering a portion of the first conductive line, a second portion of the conductive pad, and the first insulating layer.

13. The package component of claim 12, wherein the first insulating layer and the second insulating layer comprise different insulating materials.

14. The package component of claim 8, further comprising a capacitor disposed in the semiconductor portion of the substrate.

15. The package component of claim 8, further comprising at least an external conductive structure disposed on the first side of the substrate and electrically connected to the first conductive line.

16. A method for forming a package component, comprising:
receiving a substrate comprising a first conductive line on a first side of the substrate, a second conductive line on a second side of the substrate, and a conductive via penetrating the substrate to couple the first conductive line to the second conductive line, wherein the first side of the substrate is opposite to the second side of the substrate;
disposing a semiconductor structure in the substrate, wherein the semiconductor structure comprises a conductive pad on a first side of the semiconductor structure; and
forming a first redistribution layer (RDL) on the first side of the substrate and a second RDL on the second side of the substrate,
wherein a surface roughness of the conductive pad is different from a surface roughness of the first conductive line and different from a surface roughness of the second conductive line.

17. The method of claim 16, further comprising:
forming the conductive pad on the first side of the semiconductor structure;
treating a surface of the conductive pad to increase an arithmetic average roughness (Ra) of the conductive pad; and
forming an insulating layer on the first side of the semiconductor structure,
wherein a portion of the conductive pad is exposed through the insulating layer.

18. The method of claim 17, wherein the treating of the surface of the conductive pad comprises an etching.

19. The method of claim 18, wherein the treating of the surface of the conductive pad further comprises forming a bond film over the surface of the conductive pad after the etching.

20. The method of claim 16, further comprising removing a portion of the substrate prior to the disposing of the semiconductor structure in the substrate.
